(19) United States
(12) Patent Application Publication
(10) Pub. No.: US 2025/0255201 A1
(43) Pub. Date: Aug. 7, 2025

(54) SEMICONDUCTOR DEVICE, OPERATING METHOD OF THE SEMICONDUCTOR DEVICE, AND METHOD OF MANUFACTURING THE SEMICONDUCTOR DEVICE

(71) Applicant: SK hynix Inc, Icheon-si (KR)

(72) Inventor: Gap Sok DO, Icheon-si (KR)

(21) Appl. No.: 18/789,338

(22) Filed: Jul. 30, 2024

(30) Foreign Application Priority Data
Feb. 2, 2024 (KR) 10-2024-0016476

(51) Int. Cl. H10N 70/20; G11C 13/00; H10B 63/00; H10N 70/00

(52) U.S. Cl. CPC H10N 70/253; G11C 13/0011; G11C 13/0069; H10B 63/82; H10N 70/063; H10N 70/245; G11C 2213/53

(57) ABSTRACT

A transistor may include a variable resistance layer, a first electrode that is formed at a bottom of the variable resistance layer to adjust a threshold voltage of the transistor, and a second electrode and a third electrode formed at both ends of the variable resistance layer to form a current path.

### CROSS-REFERENCE TO RELATED APPLICATION

This application claims priority under 35 U.S.C. § 119 to Korean Patent Application No. 10-2024-0016476 filed on Feb. 2, 2024, which is incorporated herein by reference in its entirety.

### BACKGROUND

### 1. Technical Field

Embodiments relate to a semiconductor device and, more particularly, to a semiconductor device, an operating method of the semiconductor device, and a method of manufacturing the semiconductor device.

### 2. Related Art

Recently, as an electronic device is reduced in size, has lower power consumption and higher performance, and is diversified, a semiconductor device capable of storing information is required for various electronic devices, such as computers and portable communication devices. The semiconductor device may be basically divided into a volatile memory device and a nonvolatile memory device. The volatile memory device can retain data only when power is supplied to the volatile memory device. The nonvolatile memory device can retain data although power is not supplied to the nonvolatile memory device.

The nonvolatile memory device representatively includes NAND type memory. Next-generation memory that is now being developed includes ferroelectric RAM (FRAM), magnetic RAM (MRAM), phase-change RAM (PRAM), polymer RAM (PoRAM), and resistance RAM (ReRAM).

### SUMMARY

In an embodiment, a semiconductor device may include a variable resistance layer, a first electrode disposed at a bottom of the variable resistance layer, and a second electrode and a third electrode disposed at both ends of the variable resistance layer, respectively.

In an embodiment, a method of manufacturing a semiconductor device may include stacking a first insulating layer, a first conductive layer, a sacrificial layer, and a first mask, forming a first electrode by etching the sacrificial layer and the first conductive layer by using the first mask as an etch barrier, forming a second insulating layer on the first insulating layer, removing the sacrificial layer, forming a variable resistance material in a space from which the sacrificial layer has been removed and on the second insulating layer, forming a second mask on the variable resistance material so that the first electrode overlaps the second mask, etching the variable resistance material by using the second mask as an etch barrier to form a variable resistance layer, and forming a second electrode and a third electrode on sidewalls of the variable resistance layer, respectively.

In an embodiment, an operating method of a semiconductor device may include turning on the semiconductor device by applying a first voltage to a first electrode and applying a second voltage to each of a second electrode and a third electrode, and checking whether a current path has been formed in the semiconductor device by making floated the first electrode, applying the first voltage to the second electrode, and applying the second voltage to the third electrode. The first voltage may be a voltage having a higher voltage level than the second voltage. Each of the first to third electrodes may be formed at each end of the variable resistance layer having a T shape.

In an embodiment, an operating method of a semiconductor device may include turning off the semiconductor device by applying a second voltage to a first electrode and applying a first voltage to each of a second electrode and a third electrode and checking whether a current path has been formed in the semiconductor device by making floated the first electrode, applying the first voltage to the second electrode, and applying the second voltage to the third electrode. The first voltage may be a voltage having a higher voltage level than the second voltage. Each of the first to third electrodes may be formed at each end of the variable resistance layer having a T shape.

### BRIEF DESCRIPTION OF THE DRAWINGS

FIG. 1 is a diagram for describing a structure of a transistor included in a semiconductor device according to an embodiment of the present disclosure.

FIGS. 2A, 2B, 3A and 3B are diagrams for describing operations of the transistor included in the semiconductor device according to an embodiment of the present disclosure.

FIGS. 4A, 4B, 4C, 4D, 4E, 4F, 4G, and 4H are diagrams for describing a method of manufacturing the transistor included in the semiconductor device according to an embodiment of the present disclosure.

FIG. 5 is a diagram for describing a semiconductor device including a transistor according to an embodiment of the present disclosure.

### DETAILED DESCRIPTION

Hereinafter, embodiments according to the technical spirit of the present disclosure are described with reference to the accompanying drawings.

Embodiments of the present disclosure may provide a semiconductor device which may be manufactured by using manufacturing process similar to those of manufacturing a memory cell, an operating method of the semiconductor device, and a method of manufacturing the semiconductor device.

The size of a semiconductor device can be reduced because a transistor can be formed in a layer in which a memory cell array has been formed. As used herein, including in the claims, “or” as used in a list of items (e.g., a list of items prefaced by a phrase such as “at least one of” or “one or more of” or “one or both of”) indicates an inclusive list such that, for example, a list of at least one of A, B, or C indicates A or B or C or AB or AC or BC or ABC (i.e., A and B and C). The term “on” in the present disclosure may be used to describe a structural relationship between two adjacent elements without or with at least one intervening element therebetween. For example, when a first element is disposed “on” a second element, the first element may be disposed directly on the second element without any intervening element, or the first element may be over the second element with one or more intervening elements between the first and second elements.

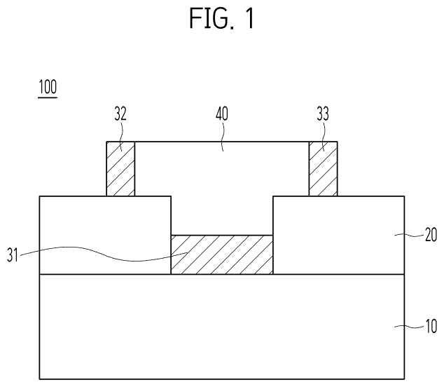

FIG. 1 is a diagram for describing a structure of a transistor included in a semiconductor device according to an embodiment of the present disclosure.

Referring to FIG. 1, a transistor 100 according to an embodiment of the present disclosure may include a variable resistance layer 40 having a T shape, a first electrode 31, a second electrode 32, and a third electrode 33.

The variable resistance layer 40 may include a resistive material, and may have a characteristic in which the state of the variable resistance layer 140 reversibly transitions between different resistance states depending on a voltage or current that is applied to the variable resistance layer 140. As an embodiment, the variable resistance layer may include a variable resistance material resistance of which is varied without a phase change, and may include a chalcogenide-based material. The variable resistance layer 40 may include at least one of germanium (Ge), antimony (Sb), tellurium (Te), arsenic (As), selenium (Se), silicon (Si), indium (In), tin (Sn), sulfur (S), or gallium (Ga). The variable resistance layer 40 may include chalcogenide that maintains an amorphous state.

The variable resistance layer 40 may be formed to have a T shape that extends in a first direction (e.g., a horizontal direction) and that extends in a second direction (e.g., a vertical direction perpendicular to the horizontal direction). For example, the variable resistance layer 40 may include a first portion (e.g., a horizontal portion in FIG. 1) extending in the first direction and a second portion (e.g., a vertical portion in FIG. 1) extending in the second direction from the first portion (e.g., the horizontal portion in FIG. 1).

The first electrode 31 may be formed at the bottom of the variable resistance layer 40, which extends in the perpendicular direction in the variable resistance layer 40 having the T shape. For example, the first electrode 31 in FIG. 1 may be disposed at a bottom of the vertical portion of the variable resistance layer 40, where the vertical portion extends in the vertical direction from the horizontal portion of the variable resistance layer 40. The first electrode 31 may be an electrode for adjusting the threshold voltage of the transistor 100 according to an embodiment of the present disclosure.

The second electrode 32 and the third electrode 33 may be formed at both ends of the variable resistance layer 40, respectively, which extend in the horizontal direction in the variable resistance layer having the T shape. For example, the second electrode 32 and the third electrode 33 may be disposed at both ends of the horizontal portion of the variable resistance layer 40, respectively. The second electrode 32 and the third electrode 33 may be electrodes that are disposed so that a current path may be formed in a portion (e.g., the horizontal portion) of the variable resistance layer 40 that extends in the horizontal direction.

The first, second, and third electrodes 31, 32, and 33 may each include a conductive material, such as polysilicon or metal. As an embodiment, the first to third electrodes 31, 32, and 33 may each include at least one of polysilicon, tungsten (W), tungsten nitride (WNx), tungsten silicide (WSix), titanium (Ti), titanium nitride (TiNx), titanium silicon nitride (TiSiN), titanium aluminum nitride (TiAIN), tantalum (Ta), tantalum nitride (TaN), tantalum silicon nitride (TaSiN), tantalum aluminum nitride (TaAIN), carbon (C), silicon carbide (SiC), silicon carbon nitride (SiCN), copper (Cu), zinc (Zn), nickel (Ni), cobalt (Co), lead (Pd), platinum (Pt), molybdenum (Mo), or ruthenium (Ru).

The transistor 100 according to an embodiment of the present disclosure may be formed in a form in which the transistor 100 is surrounded by insulating layers 10 and 20. As an embodiment, in the transistor 100, the insulating layers 10 and 20 may be formed to surround a lower part of the variable resistance layer 40 that extends in the horizontal direction in the variable resistance layer 40 having the T shape. For example, the insulating layer 20 and the first electrode may be disposed substantially coplanar on the insulating layer 10, and the insulating layer 20 may be disposed to wrap around the vertical portion of the variable resistance layer 40 as well as the first electrode 31. In particular, the insulating layer 20 may be formed to be disposed on both sides of the variable resistance layer 40 between the second electrode 32 and the first electrode 31 and between the third electrode and the first electrode 31. For example, the insulating layer 20 may be disposed on a first side (e.g., a left side in FIG. 1) of the vertical portion of the variable resistance layer between the second electrode and the first electrode 31 and on a second side (e.g., a right side in FIG. 1) of the vertical portion of the variable resistance layer between the third electrode 33 and the first electrode 31. The insulating layers and 20 may each include an insulating material, such as oxide, silicon oxide, nitride, or silicon nitride. The insulating layers 10 and 20 may each be a single layer or a multilayer film.

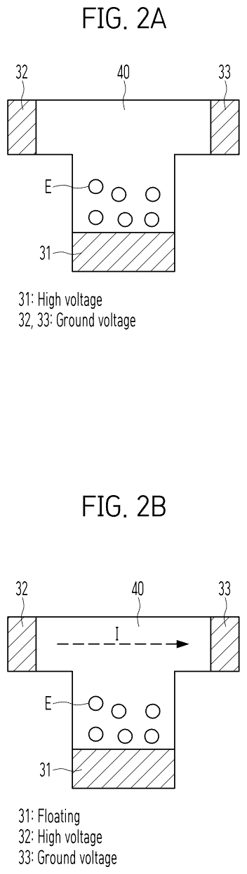

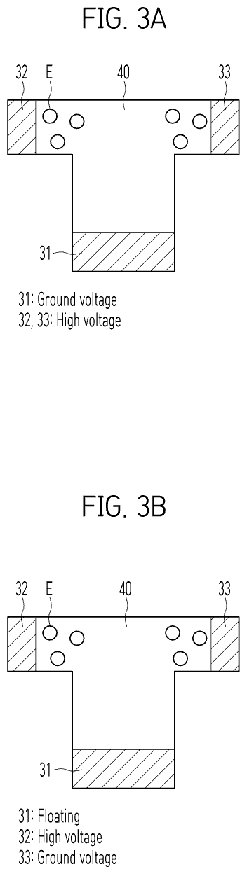

FIGS. 2A, 2B, 3A, and 3B are diagrams for describing operations of the transistor included in the semiconductor device according to an embodiment of the present disclosure.

FIGS. 2A and 2B illustrate a turn-on operation of the transistor according to an embodiment of the present disclosure.

Referring to FIG. 2A, a first voltage (e.g., High voltage) may be applied to the first electrode 31. A second voltage (e.g., Ground voltage) may be applied to the second and third electrodes 32 and 33. In this case, the first voltage (e.g., High voltage) may have a higher voltage level than the second voltage (e.g., Ground voltage). In such a case, a specific element E within the variable resistance layer 40 having the T shape may move in the direction of the first electrode 31. As a result, content of the specific element E in the horizontal portion of the variable resistance layer 40 decreases, thereby reducing a threshold voltage of the transistor to form a current path I through the horizontal portion of the variable resistance layer 40 as will be described below referring to FIG. 2B.

Referring to FIG. 2B, the first electrode 31 may be made floated (Floating). The first voltage (e.g., High voltage) may be applied to the second electrode 32. The second voltage (e.g., Ground voltage) may be applied to the third electrode 33. In such a case, a current I may flow from the second electrode 32 to the third electrode 33 because a current path is formed in the variable resistance layer 40 that extends in the horizontal direction between the second electrode 32 and the third electrode 33.

FIGS. 3A and 3B illustrate a turn-off operation of the transistor according to an embodiment of the present disclosure.

Referring to FIG. 3A, the second voltage (e.g., Ground voltage) may be applied to the first electrode 31. The first voltage (e.g., High voltage) may be applied to the second and third electrodes 32 and 33. In such a case, the specific element E within the variable resistance layer 40 having the T shape may move to the variable resistance layer that extends in the horizontal direction between the second and third electrodes 32 and 33. The specific element E may be an electronegative element. For example, when the first voltage (e.g., High voltage) is applied to the second and third electrodes 32 and 33 and the second voltage (e.g., Ground voltage) is applied to the first electrode 31, the negatively charged ions of the specific element E move from a lower region of the vertical portion of the variable resistance layer 40 towards end regions of the horizontal portion of the variable resistance layer 40. As a result, content of the specific element E in the horizontal portion of the variable resistance layer 40 increases, thereby increasing a threshold voltage of the transistor to form a current path I through the horizontal portion of the variable resistance layer 40 as will be described below referring to FIG. 3B. In some embodiments, the specific element E may be an electropositive element. In these embodiments, although not shown, a first voltage (e.g., High voltage) may be applied to the first electrode 31 and the second voltage (e.g., Ground voltage) may be applied to the second and third electrodes 32 and 33. For example, the first voltage (e.g., High voltage) is applied to the first electrode 31 and the second voltage (e.g., Ground voltage) is applied to the second and third electrodes 32 and 33, the positively charged ions of the specific element E move from a lower region of the vertical portion of the variable resistance layer 40 towards end regions of the horizontal portion of the variable resistance layer 40. As a result, content of the specific element E in the horizontal portion of the variable resistance layer 40 increases, thereby increasing a threshold voltage of the transistor to form a current path I through the horizontal portion of the variable resistance layer 40 as will be described below referring to FIG. 3B. Although the first voltage (e.g., High voltage) is applied to the second and third electrodes 32 and 33 and the second voltage (e.g., Ground voltage) is applied to the first electrode 31 in the embodiment of FIG. 3A, embodiments of the present disclosure are not limited thereto. For example, although not shown, when specific element E is an electronegative element, the first voltage may be applied to the second electrode 32 and the second voltage may be applied to the first and third electrodes 31 and 33. As a result, the negatively charged ions of the specific element E move from a lower region of the vertical portion of the variable resistance layer 40 towards an end region of the horizontal portion of the variable resistance layer 40 adjacent to the second electrode 32 to which the first voltage is applied, thereby increasing a threshold voltage of the transistor to form a current path I through the horizontal portion of the variable resistance layer 40.

Referring to FIG. 3B, the first electrode 31 may be made floated (Floating). The first voltage (e.g., High voltage) may be applied to the second electrode 32. The second voltage (e.g., Ground voltage) may be applied to the third electrode 33. In such a case, a current path might not be formed in the variable resistance layer 40 between the second electrode 32 and the third electrode 33 due to the specific element E. That is, a current might not flow from the second electrode to the third electrode 33.

As a result, the transistor 100 according to an embodiment of the present disclosure may have a higher threshold voltage and may be turned off, as the number of specific elements E is increased within the variable resistance layer 40 that extends in the horizontal direction between the second electrode 32 and the third electrode 33.

The transistor 100 according to an embodiment of the present disclosure may have a lower threshold voltage and may be turned on, as the number of specific elements E is reduced within the variable resistance layer 40 that extends in the horizontal direction between the second electrode 32 and the third electrode 33.

Accordingly, an operation of reducing content of the specific element E in the horizontal portion of the variable resistance layer 40 may be referred to as an operation of lowering the threshold voltage of the transistor 100 or an operation of turning on the transistor 100. For example, an operation of applying the first voltage (e.g., High voltage) to the first electrode 31 and applying the second voltage (e.g., Ground voltage) to the second and third electrodes 32 and 33 as shown in FIG. 2A may be referred to as an operation of lowering the threshold voltage of the transistor 100 or an operation of turning on the transistor 100.

An operation of increasing content of the specific element E in the horizontal portion of the variable resistance layer 40 may be referred to as an operation of raising the threshold voltage of the transistor 100 or an operation of turning off the transistor 100. For example, an operation of applying the second voltage (e.g., Ground voltage) to the first electrode 31 and applying the first voltage (e.g., High voltage) to the second and third electrodes 32 and 33 as shown in in FIG. 3A may be referred to as an operation of raising the threshold voltage of the transistor 100 or an operation of turning off the transistor 100.

Furthermore, after a turn-on operation and turn-off operation for the transistor 100 according to an embodiment of the present disclosure, the first electrode 31 may be made floated, the first voltage (e.g., High voltage) may be applied to the second electrode 32, and the second voltage (e.g., Ground voltage) may be applied to the third electrode 33. At this time, the transistor 100 on which the turn-on operation has been performed may make flow a current from the second electrode 32 to the third electrode 33. A current might not flow into the transistor 100 on which the turn-off operation has been performed because a current path is not formed between the second electrode 32 and the third electrode 33. Accordingly, the operation of making floated the first electrode 31, applying the first voltage (e.g., High voltage) to the second electrode 32, and applying the second voltage (e.g., Ground voltage) to the third electrode 33 may be referred to as an operation of checking whether a current path has been formed in the transistor.

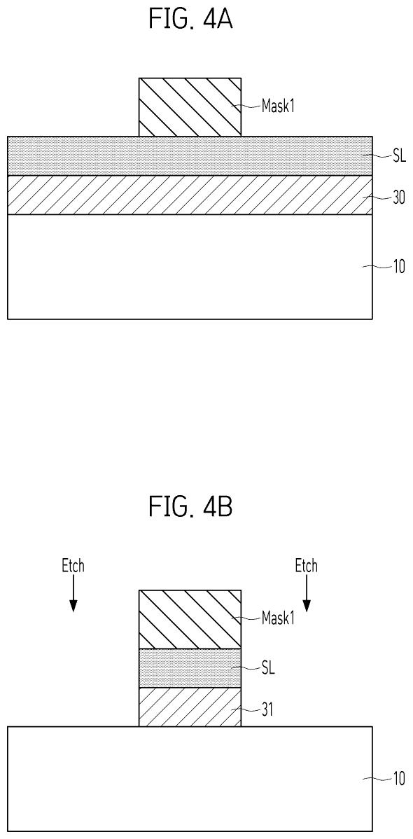

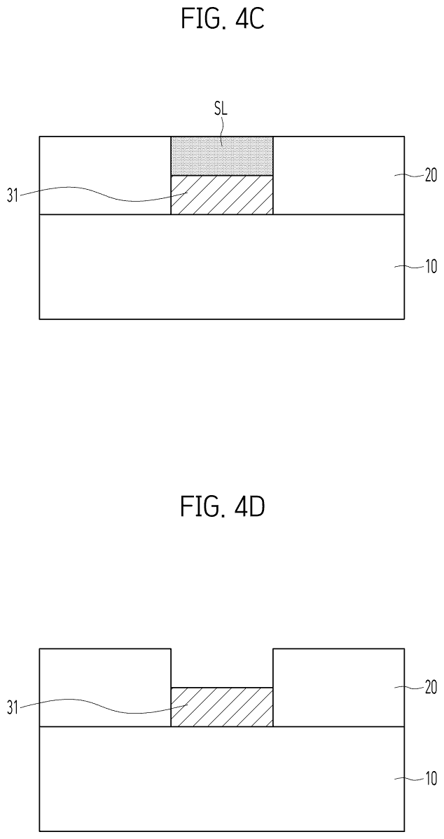

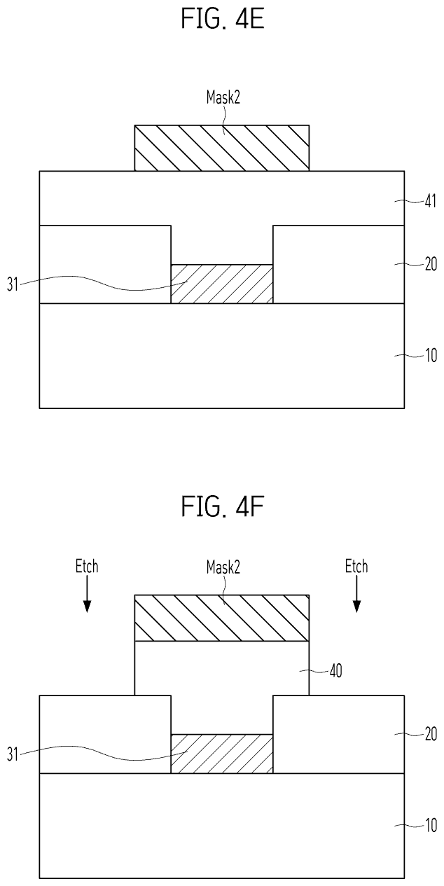

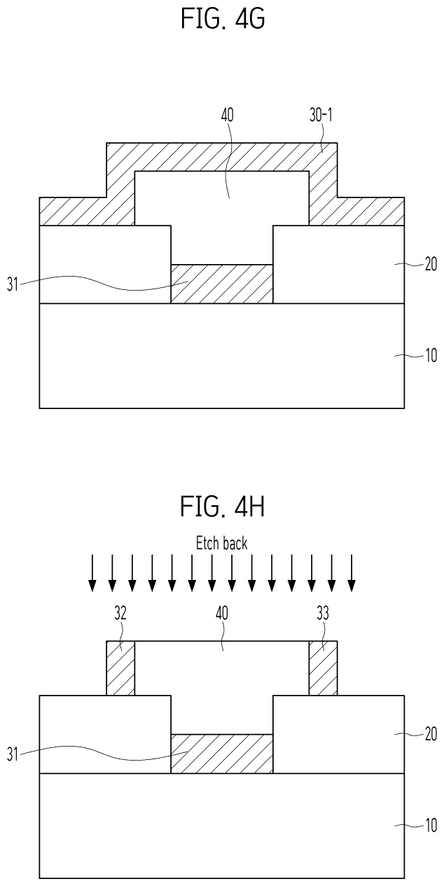

FIGS. 4A to 4H are diagrams for describing a method of manufacturing the transistor included in the semiconductor device according to an embodiment of the present disclosure.

Referring to FIG. 4A, a first insulating layer 10, a first conductive layer 30, a sacrificial layer SL, and a first mask Mask1 may be stacked.

For example, the first conductive layer 30 may be formed on the insulating layer 10. The sacrificial layer SL may be formed on the first conductive layer 30. The first mask Mask1 may be formed on the sacrificial layer SL. The first insulating layer 10 may include an insulating material, such as oxide, silicon oxide, nitride, or silicon nitride. The insulating layer 10 may be a single layer or a multilayer film. The first conductive layer 30 may include a conductive material, such as polysilicon or metal. As an embodiment, the conductive layer may include at least one of polysilicon, tungsten (W), tungsten nitride (WNx), tungsten silicide (WSix), titanium (Ti), titanium nitride (TiNx), titanium silicon nitride (TiSiN), titanium aluminum nitride (TiAIN), tantalum (Ta), tantalum nitride (TaN), tantalum silicon nitride (TaSiN), tantalum aluminum nitride (TaAIN), carbon (C), silicon carbide (SiC), silicon carbon nitride (SiCN), copper (Cu), zinc (Zn), nickel (Ni), cobalt (Co), lead (Pd), platinum (Pt), molybdenum (Mo), or ruthenium (Ru).

Referring to FIG. 4B, the first electrode 31 may be formed. As an embodiment, the first electrode 31 may be formed by etching the sacrificial layer SL and the first conductive layer 30 by using the first mask Mask1 as an etch barrier.

Referring to FIG. 4C, the second insulating layer 20 may be formed. As an embodiment, the second insulating layer 20 may be deposited, and a planarization process (e.g., chemical-mechanical polishing CMP) may be performed up to the sacrificial layer SL. At this time, the first mask Mask1 may be removed by the planarization process CMP.

Referring to FIG. 4D, the sacrificial layer SL may be removed.

Referring to FIG. 4E, a variable resistance material 41 may be formed. As an embodiment, the variable resistance material 41 may be formed in a space from which the sacrificial layer SL has been removed, that is, on the first electrode 31 and within the second insulating layer 20. Furthermore, the variable resistance material 41 may be formed on the second insulating layer 20. A second mask Mask2 may be formed on the variable resistance material 41. In this case, the second mask Mask2 may be disposed at a location where the second mask Mask2 may overlap the first electrode 31 and may be formed to have a size capable of overlapping the first electrode 31. In the embodiment of FIG. 4E, the second mask Mask2 may be disposed over the first electrode 31 and have a sufficient size (e.g., horizontal width in FIG. 4E) to encompass the first electrode 31 and portions of the second insulating layer 20 when seen in a top view. As a result, a variable resistance layer 40 in FIG. 4F may be formed to have a T shape after an etching process is completed while protecting the first electrode 31 during the etching process that will be described below with reference to FIG. 4F.

Referring to FIG. 4F, a variable resistance layer 40 having a T shape according to an embodiment of the present disclosure may be formed. As an embodiment, the variable resistance layer 40 having the T shape may be formed by etching the variable resistance material 41 by using the second mask Mask2 as an etch barrier.

Referring to FIG. 4G, a second conductive layer 30-1 may be formed. As an embodiment, after the second mask Mask2 is etched or removed by a planarization process, the second conductive layer 30-1 may be formed on the second insulating layer 20, on the sidewalls of the variable resistance layer 40, and on the variable resistance layer 40.

Referring to FIG. 4H, the second electrode 32 and the third electrode 33 may be formed. As an embodiment, the second and third electrodes 32 and 33 may be formed on both sidewalls of the variable resistance layer 40 by removing portions of the second conductive layer 30-1 that have been formed on the second insulating layer 20 and the variable resistance layer 40 through an etch back process. For example, the second and third electrodes 32 and 33 may be formed by removing portions of the second conductive layer 30-1 that have been formed on the second insulating layer 20 and an upper surface of the variable resistance layer 40 through an etch back process. As a result, portions of the second conductive layer 30-1 that have been formed on both sides of the variable resistance layer 40 remain after the etch back process. Although not shown, a cell array may be formed at the same layer as a transistor including the variable resistance layer 40, the first electrode 31, the second electrode 32, and the third electrode 33.

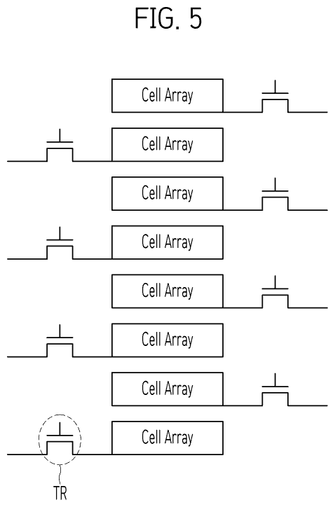

FIG. 5 is a diagram for describing a semiconductor device including a transistor (e.g., the transistor 100 in FIG. 1) according to an embodiment of the present disclosure.

Referring to FIG. 5, the semiconductor device may include a plurality of cell arrays and a plurality of transistors TR each of which has been stacked. In this case, the plurality of cell arrays may each include a memory cell in which a variable resistance layer is used as a memory layer. Furthermore, the plurality of transistors TR may be formed through a manufacturing method, such as that described with reference to FIGS. 4A to 4H. The plurality of transistors TR may each be formed by using the same materials (e.g., the material of the variable resistance layer and the material of the electrode) as those of the memory cell of the cell array. Accordingly, the transistor TR may be formed on the same layer as each cell array.

As a result, a transistor according to an embodiment of the present disclosure may be formed at the same layer as a cell array including a plurality of memory cells each including a variable resistance layer. Furthermore, a plurality of transistors may be stacked when a plurality of cell arrays are stacked. In other words, a plurality of transistors according to an embodiment of the present disclosure may be stacked together with a plurality of cell arrays. For example, a first transistor and a first cell array may be formed at a first layer, a second transistor and a second cell array may be formed at a second layer over the first layer, and so forth. As a result, a degree of integration of a semiconductor device including a plurality of stacked transistors according to an embodiment may be increased compared to a conventional semiconductor device including a plurality of transistors that are formed on a single substrate.

Although embodiments according to the technical spirit of the present disclosure have been described above with reference to the accompanying drawings, the embodiments have been provided to merely describe embodiments according to the concept of the present disclosure, and the present disclosure is not limited to the embodiments. A person having ordinary knowledge in the art to which the present disclosure pertains may substitute, modify, and change the embodiments in various ways without departing from the technical spirit of the present disclosure written in the claims. Such substitutions, modifications, and changes may be said to belong to the scope of the present disclosure.

What is claimed is:

1. A semiconductor device comprising:
a variable resistance layer;
a first electrode disposed at a bottom of the variable resistance layer; and
a second electrode and a third electrode disposed at both ends of the variable resistance layer, respectively.

2. The semiconductor device of claim 1, further comprising an insulating layer on a first side of the variable resistance layer between the second electrode and the first electrode and a second side of the variable resistance layer between the third electrode and the first electrode.

3. The semiconductor device of claim 1, wherein the variable resistance layer has a T shape.

4. The semiconductor device of claim 1, wherein the variable resistance layer comprises a resistive material.

5. The semiconductor device of claim 4, wherein the variable resistance layer comprises a chalcogenide-based material.

6. The semiconductor device of claim 1, wherein a transistor includes the variable resistance layer, the first electrode, the second electrode, and the third electrode, and
wherein a current path is formed in the variable resistance layer between the second and third electrodes based on a level of a voltage that is applied to the first electrode.

7. The semiconductor device of claim 6, wherein the voltage that is applied to the first electrode adjusts a threshold voltage of the transistor.

8. The semiconductor device of claim 6, wherein the transistor is a first transistor formed at a first layer, the device further comprising a first cell array formed at the first layer.

9. The semiconductor device of claim 8, wherein the variable resistance layer of the first transistor is a first variable resistance layer, the device further comprising:
a second transistor formed at a second layer over the first layer and including a second variable resistance layer, a fourth electrode disposed at a bottom of the second variable resistance layer, a fifth electrode and a sixth electrode disposed at both ends of the second variable resistance layer, respectively; and
a second cell array formed at the second layer.

10. The semiconductor device of claim 8, wherein the variable resistance layer of the first transistor is a first variable resistance layer, and the first cell array includes a plurality of memory cells, each of the plurality of memory cells including a second variable resistance layer,
wherein the first variable resistance layer and the second variable resistance layer include a common material.

11. A method of manufacturing a semiconductor device, comprising:
stacking a first insulating layer, a first conductive layer, a sacrificial layer, and a first mask;
forming a first electrode by etching the sacrificial layer and the first conductive layer by using the first mask as an etch barrier;
forming a second insulating layer on the first insulating layer;
removing the sacrificial layer;
forming a variable resistance material in a space from which the sacrificial layer has been removed and on the second insulating layer;
forming a second mask on the variable resistance material so that the first electrode overlaps the second mask;
etching the variable resistance material by using the second mask as an etch barrier to form a variable resistance layer; and
forming a second electrode and a third electrode on sidewalls of the variable resistance layer, respectively.

12. The method of claim 11, wherein the forming of the second electrode and the third electrode comprises:
removing the second mask;
forming a second conductive layer on the second insulating layer, the sidewalls of the variable resistance layer, and an upper surface of the variable resistance layer; and
removing portions of the second conductive layer that have been formed on the second insulating layer and the upper surface of the variable resistance layer.

13. The method of claim 11, wherein the second mask has a size sufficient to encompass the first electrode when seen in a top view.

14. The method of claim 11, wherein a transistor includes the variable resistance layer, the first electrode, the second electrode, and the third electrode, the method further comprising forming a cell array at the same layer as the transistor.

15. An operating method of a semiconductor device including a transistor, wherein the transistor includes a first electrode, a second electrode, and a third electrode, the method comprising:
turning on the transistor by applying a first voltage to the first electrode and applying a second voltage to each of the second electrode and the third electrode; and
checking whether a current path has been formed in the transistor by floating the first electrode, applying the first voltage to the second electrode, and applying the second voltage to the third electrode,
wherein the first voltage has a level higher than that of the second voltage, and
wherein each of the first, second, and third electrodes is formed at a corresponding end of the variable resistance layer that has a T shape.

16. The operating method of claim 15, wherein the second and third electrodes are formed at both ends of the variable resistance layer that extends in a horizontal direction, respectively.

17. The operating method of claim 15, wherein the first electrode is formed at a bottom of the variable resistance layer that extends in a vertical direction.

18. An operating method of a semiconductor device including a transistor, wherein the transistor includes a first electrode, a second electrode, and a third electrode, the method comprising:
turning off the transistor by applying a second voltage to the first electrode and applying a first voltage to one or both of the second electrode and the third electrode; and
checking whether a current path has been formed in the transistor by floating the first electrode, applying the first voltage to the second electrode, and applying the second voltage to the third electrode,
wherein the first voltage has a level higher than that of the second voltage, and
wherein each of the first, second, and third electrodes is formed at a corresponding end of the variable resistance layer that has a T shape.

19. The operating method of claim 18, wherein the second and third electrodes are formed at both ends of the variable resistance layer that extends in a horizontal direction, respectively.

20. The operating method of claim 18, wherein the first electrode is formed at a bottom of the variable resistance layer that extends in a vertical direction.
